(19) United States
(12) Patent Application Publication
(10) Pub. No.: US 2024/0351032 A1
(43) Pub. Date: Oct. 24, 2024

(54) MICROFLUIDICS DEVICES AND METHODS

(71) Applicant: THE GOVERNING COUNCIL OF THE UNIVERSITY OF TORONTO, Toronto (CA)

(72) Inventors: Sebastian VON DER ECKEN, Concord (CA); Aaron R. WHEELER, Toronto (CA); Michael Dean CHAMBERLAIN, Saskatoon (CA); Alexandros SKLAVOUNOS, Toronto (CA)

(21) Appl. No.: 18/708,902

(22) PCT Filed: Nov. 10, 2022
(86) PCT No.: PCT/CA2022/051661

§ 371 Date: May 9, 2024

Related U.S. Application Data
(60) Provisional application No. 63/278,787, filed on Nov. 12, 2021.

(51) Int. Cl. B01L 3/00; B81B 1/00

(52) U.S. Cl. CPC B01L 3/502715; B01L 3/502784; B01L 2300/041; B01L 2300/0645; B01L 2300/12; B01L 2300/123; B01L 2400/0415; B81B 1/00

(57) ABSTRACT

A microfluidics device comprises a cover mounted to an addressing structure. The cover has a working surface on one side, and a plurality of electrodes on its other side. The electrodes may be used for manipulation of fluid droplets on the working surface. The electrodes are connected to a voltage source by way of the addressing structure to selectively apply voltage to individual ones of the plurality of electrodes.

### RELATED APPLICATIONS

This claims priority from U.S. provisional patent application No. 63/278,787, filed Nov. 12, 2021, the entire contents of which are incorporated herein by reference.

### FIELD

This disclosure relates to microfluidics, and more particularly to design and construction of microfluidics devices.

### BACKGROUND

In a typical microfluidics device, fluids, e.g., droplets of reagents, are manipulated on a working surface for performing procedures such as experiments, assays, sampling or production processes. The working surface includes an array of electrodes. The electrodes of the working surface are connected to an electrical control system, which can selectively apply voltages to electrodes. In some microfluidics devices, which may be referred to as two-plate devices, a top plate is positioned above the working surface. In other microfluidics devices, which may be referred to as one-plate devices, no top plate is present. When a voltage is applied to one or more electrodes of the working surface, a droplet adjacent to the electrode experiences an electrostatic force that can be used to automatically move, dispense, merge and mix droplets of different reagents.

The electrodes of the working surface are generally coupled to the electrical control system by a series of conductive traces. Unfortunately, existing designs for such traces have deficiencies. For example, one technique involves patterning of electrodes and traces in a single layer of a substrate such as a semiconductor die. However, this technique requires conductive traces to be routed between electrodes, requiring the electrodes to be spaced farther apart to accommodate the conductive traces. Such spacing limits the density of electrodes. In some cases, spacing between electrodes may be large enough to interfere with manipulation of droplets on the working surface.

Another technique involves routing of conductive traces through vertical vias. In such devices, conductive traces are routed in a separate bus layer of a printed circuit board (PCB). The conductive traces are connected to surface-mounted electrodes by way of vertical vias. However, a typical PCB surface has deep vertical trenches or ruts which can interfere with droplet movement.

### SUMMARY

An example microfluidics device comprises: a cover with a first side defining a working surface; a plurality of electrodes on a second side of the cover for manipulation of fluid droplets on the working surface; and an addressing structure for contacting the second side of the cover and coupled to a voltage source to selectively apply voltage to individual ones of the plurality of electrodes; the cover mounted to the addressing structure to electrically couple the electrodes to the addressing structure.

In some embodiments, the addressing structure comprises a plurality of electrode pads coupled to the voltage source by a plurality of conductive traces through the addressing structure.

In some embodiments, the addressing structure comprises a printed circuit board.

In some embodiments, the addressing structure comprises a semiconductor die.

In some embodiments, the addressing structure comprises a photoconductive layer for selectively connecting ones of the electrodes to a voltage source by application of light.

In some embodiments, the cover comprises a sheet of dielectric material.

In some embodiments, the plurality of electrodes are patterned onto the sheet of dielectric material.

In some embodiments, the cover comprises aluminum-coated polyimide film.

In some embodiments, the cover comprises a flexible film.

In some embodiments, the thickness of the cover is between 2.5 μm and 50 μm.

In some embodiments, the thickness of the cover is between than 7.5 μm and 12.5 μm.

In some embodiments, the cover is removably mounted to the addressing structure.

In some embodiments, the cover is removably mounted to the addressing structure by application of vacuum pressure.

In some embodiments, the cover is mounted to the addressing structure using an adhesive.

In some embodiments, the addressing structure includes a plurality of through-holes.

In some embodiments, the microfluidics device comprises a light source positioned to illuminate the working surface through the through-holes.

In some embodiments, the cover is dispensed from a roll.

In some embodiments, the microfluidics device comprises a plate positioned opposite the working surface for contacting a droplet on the working surface.

In some embodiments, the voltage source is an integrated circuit for controlling the microfluidics device, the integrated circuit mounted to the printed circuit board and electrically coupled to the plurality of electrode pads.

In some embodiments, the voltage source is an integrated circuit for controlling the microfluidics device, the integrated circuit formed on the semiconductor die.

In some embodiments, the integrated circuit receives a data stream, the data stream comprising instructions for controlling the microfluidics device.

In some embodiments, the voltage source comprises a digital control system.

In some embodiments, the microfluidics device comprises a plurality of ground electrodes patterned on the first side of the cover.

Microfluidics devices according to the present disclosure may include the above features in any operable combination.

An example microfluidics method, comprises: mounting a cover atop an addressing structure, the cover defining a working surface on a first side thereof and having a plurality of electrodes on a second side thereof, the addressing structure configured to selectively couple ones of the electrodes to a voltage source to cause movement of fluid droplets on the working surface.

In some embodiments, the addressing structure comprises a plurality of electrode pads coupled to the voltage source by a plurality of conductive traces through the addressing structure.

In some embodiments, the addressing structure comprises a printed circuit board.

In some embodiments, the addressing structure comprises a semiconductor die.

In some embodiments, the addressing structure comprises a photoconductive layer for selectively connecting ones of the electrodes to a voltage source by application of light.

In some embodiments, the cover comprises a flexible film.

In some embodiments, the method comprises mounting the cover to the addressing structure by application of vacuum pressure.

In some embodiments, the method comprises mounting the cover to the addressing structure using an adhesive.

In some embodiments, the method comprises removing the cover from the mounting structure and mounting a second cover atop the addressing structure.

In some embodiments, the method comprises dispensing the second cover by advancing a roll of film.

In some embodiments, the voltage source is an integrated circuit for controlling the movement of fluid droplets on the working surface, the integrated circuit mounted to the printed circuit board and electrically coupled to the plurality of electrode pads.

In some embodiments, the voltage source is an integrated circuit for controlling the movement of fluid droplets on the working surface, the integrated circuit formed on the semiconductor die.

In some embodiments, the integrated circuit receives a data stream, the data stream comprising instructions for controlling the movement of fluid droplets on the working surface.

In some embodiments, the cover comprises a plurality of ground electrodes patterned on the first side.

Methods according to the present disclosure may include the above features in any operable combination.

An example microfluidics device comprises: a top plate; a base, comprising: a cover with a first side defining a working surface facing the top plate; a plurality of electrodes on a second side of the cover for manipulation of fluid droplets on the working surface; and an addressing structure comprising a plurality of electrode pads coupled to an electrical control system by a plurality of conductive traces through the addressing structure; the cover mounted to the addressing structure to electrically couple the electrodes to the addressing structure.

Other aspects with be apparent from the detailed description.

### BRIEF DESCRIPTION OF THE DRAWINGS

In the figures, which illustrate example embodiments:

FIG. 1A is a top view of a microfluidics device;

FIG. 1B is an exploded view of the microfluidics device of FIG. 1A, showing a working surface;

FIG. 1C is a partial side cross-sectional view of the microfluidics device of FIG. 1A;

FIG. 2 is an enlarged top view of a region of the working surface of FIG. 1B;

FIG. 3 is a partial side cross-sectional view of the microfluidics device of FIG. 1B, showing a mounting technique;

FIG. 4 perspective view of a cover being removed from an addressing structure;

FIG. 5 is a schematic view of electrodes of a microfluidics device cover;

FIG. 6 is a schematic view of electrodes of a microfluidics device cover;

FIG. 7 is a schematic view of electrodes of a microfluidics device cover;

FIGS. 8A-8B are top schematic views of microfluidics device covers;

FIG. 9 is a partial exploded view of another microfluidics device, with a top plate omitted;

FIGS. 10A-10D are cross-sectional views of techniques for mounting a cover to a routing structure;

FIG. 11 is a top view of a microfluidics device with a sheet of replaceable covers;

FIG. 12A is a top view of a microfluidics device, with sheets of replaceable covers and top plates;

FIG. 12B is a cross-sectional view of the microfluidics device of FIG. 12A, taken at section line B-B shown in FIG. 12A;

FIG. 13 is a partial cross-sectional view of another microfluidics device; and

FIGS. 14A-14B are partial side cross-sectional views of another microfluidics device.

### DETAILED DESCRIPTION

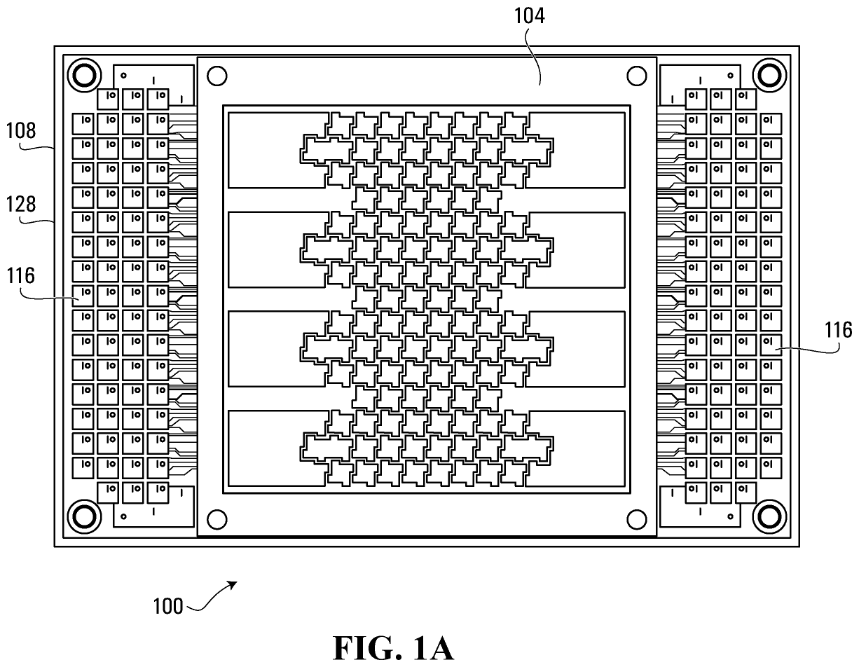

FIGS. 1A-1B depict a microfluidics device 100 in top and exploded views, respectively. Microfluidics device 100 is a two-plate device and includes a top plate 104 disposed on top of a base 108. However, as will be apparent, the present disclosure is also applicable to microfluidics devices which lack a top plate.

Top plate 104 may be formed of glass. For example, top plate 104 may be an indium tin oxide (ITO) coated glass slide. In the depicted embodiment, top plate 104 includes one or more conductive elements, such as electrodes or a conductive layer or coating, for electrically grounding or applying a bias voltage to the top plate. Alternatively, electrodes may be omitted from the top plate. The top plate 104 may further include one or more of a dielectric coating and a hydrophobic coating or covering on its underside, facing base 108.

A working surface 146 is defined on a top side of a cover 124 atop base 108 and positioned immediately beneath top plate 104. A plurality of electrodes 150 are positioned beneath working surface 146. Electrodes 150 include driving electrodes 151, reservoir electrodes 153 and dispensing electrodes 155. Although cover 124 may include opaque layers above electrodes 150 which may obscure the electrodes from view, details of the electrodes are shown in FIGS. 1A-1B for purposes of illustration.

Base 108 has a plurality of control contacts (e.g., contact pads) 116 for connection to a voltage source, e.g., an electrical control system such as a digital control system. Control contacts 116 are coupled to electrodes 150 to apply voltages to the electrodes, ground the electrodes or to deliver current to the electrodes. The control contacts 116 may be distributed in any suitable configuration on base 108. As depicted, control contacts 116 are external contact pads positioned near the periphery of base 108 and electrodes 150 are positioned closer to the center of base 108. However, in other embodiments, control contacts 116 may be positioned on another surface of base 108, e.g., on the underside of base 108, or on a rigid-flex PCB extension of base 108. Alternatively, connection to a control system may be by way of one or more cable connectors.

Control contacts 116 are coupled to electrodes 150 by way of an addressing structure. The addressing structure allows a control signal or voltage to be applied to one or more selected electrodes 150, e.g., by way of conductive traces 120 routed through the addressing structure.

FIG. 1C is a partial side cross-sectional view of microfluidics device 100. As shown, top plate 104 is elevated above cover 124 to accommodate droplet 158. The top plate may be externally supported by suitable supports or spacers. In some examples, top plate 104 is spaced apart from cover 124 by a distance between ⅓ and 1/20 of the size of electrodes 150. Typically, such spacing is between 80 and 300 μm. However, the spacing may be larger (e.g., 1-2 millimeters) or smaller (e.g., as little as 10 μm), and the ratio of top plate spacing to electrode size may be smaller or larger. For example, some devices may include long and narrow electrodes as little as 100 μm in width and several millimeters in length, in which case spacing between cover 124 and top plate 104 may be greater than the width of the electrodes.

Top plate 104 may include a hydrophobic layer on its underside, such that the hydrophobic layer contacts droplet 158.

Droplet 158 may include, for example, reagents, or samples for assay. Droplet 158 may include an aqueous solution, which may, for example, be prepared with deionized water (DI H₂O) with a resistivity of >18 MΩ·cm and supplemented with 0.05 w/w % ethylenediaminetetrakis (ethoxylate-block-propoxylate) tetrol. In some embodiments, droplet 158 may include particles such as magnetic beads.

An electrical control system 164 may be electrically coupled to top plate 104 and to electrodes 150 by way of control contacts 116 (FIGS. 1A-1B). The electrical control system 164 may ground top plate 104 or apply an electrical bias or control signal to top plate 104. An example of a suitable electrical control system 164 is a Drop-Bot digital microfluidic control system which may run MicroDrop software, described in R. Fobel, C. Fobel and A. R. Wheeler, “DropBot: An open-source digital microfluidic control system with precise control of electrostatic driving force and instantaneous drop velocity measurement,” Applied Physics Letters, vol. 102, pp. 193513-5, 2013.

Electrical control system 164 may selectively control voltage signals provided to each of electrodes 150. For example, some electrodes may be grounded or provided with an electrical bias signal, while other selected electrodes 150 may simultaneously receive an actuation signal from electrical control system 164 that is different from the bias signal. The bias and control signals may be AC or DC. For example, AC voltages may be 5 V, 10-30 V, 20-200 Volt or 50-200 V and +0-10 Hz, 1-100 Hz, 100-10000 Hz or 10-100,000 Hz. Such signals may, for example, comprise sine waves, saw waves, rectangular waves, tan waves or the like. In most digital microfluidics applications, such signals are between 10-400 V and 0-20,000 Hz. However, in some examples, voltages or frequencies may differ. For example, very high voltages (e.g., higher than 1,000 V) may be used to move fluids or droplets by di-electrophoresis.

In an example, the bias signal may hold top plate 104 and inactive ones of electrodes 150 to a ground or other reference voltage, and the actuation signal may activate other ones of electrodes 150 with a signal including sine waves of up to 155 V_{RMS} at 10 KHz relative to the reference voltage.

The applied voltages create voltage differentials between adjacent electrodes 150, which may in turn exert electrostatic or electrowetting forces on droplets. Droplets 158 may be physically moved between electrodes using such electrostatic forces, according to a desired droplet manipulation process to be performed. For example, droplets 158 of may be mixed with one another by movement of multiple droplets onto common electrodes 150.

In some embodiments, the electrical control system 164 may be integrated with microfluidics device 100. For example, electrical control system 164 may include an integrated circuit (IC) or application specific IC (ASIC), which may be integrated with base 108 and thus connected directly to control contacts 116. In such embodiments, electrical control system 164 may receive a data stream, such as through a serial connection, and DC power externally from base 108. The electrical control system may apply voltages to the electrodes, ground the electrodes or deliver current to the electrodes, depending on the data stream. Alternatively, the electrical control system may be integrated with base 108 in a single IC, such as a single semiconductor die, such that electrical control system is a circuit block on the IC. In such embodiments, as shown in FIG. 1C, base 108 includes a cover 124 and an addressing structure 128. In the depicted embodiment, addressing structure 128 includes a printed circuit board (PCB) 129, which may include other discrete and integrated electronic components, such as ICs and transistors (not shown). Control contacts 116 are formed as pads atop PCB 129. Traces 120 are routed through PCB 129, which includes one or more bus layers of traces 120. Traces 120 may include vias extending vertically through the PCB and connecting layers. The number of layers may be determined, for example, according to the number of electrodes 150 which must be coupled to electrical control system 164. Multiple routing layers may be required if large numbers of electrodes are present. Alternatively, in embodiments with relatively few electrodes, routing may be simpler and may be achieved with as little as a single layer.

Addressing structure 128 also includes electrode pads 134. In the depicted embodiment, electrode pads 134 are formed atop PCB 129 and are spatially distributed in an array. Electrode pads 134 are coupled or connected to conductive traces 120. Specifically, in the depicted embodiment, electrode pads 134 are coupled to vertical portions of traces 120. Accordingly, conductive traces may be routed beneath electrode pads 134, rather than between electrode pads 134 on the same layer. Electrode pads 134 may therefore be densely spaced atop addressing structure 128, provided that the electrode pads 134 are spaced sufficiently away from one another to avoid capacitive or inductive coupling between electrode pads 134 and conductive traces 120. The minimum distance between electrode pads 134 and traces 120 required to avoid dielectric breakdown depends on the voltage applied and the dielectric strength of the substrate.

Electrode pads 134 project upwardly from the top surface of PCB 129 by an electrode pad height 138, namely, the vertical height from the surface of PCB 129 to the top of electrode pads 134. The prominence of electrode pads 134 atop PCB 129 results in roughness at the top of the addressing structure. The electrode pad height 138 may depend on the PCB layer thickness. For example, typical thicknesses are defined in increments of 0.5 oz, e.g., 0.5 oz and 1 oz, where 1 oz=34.7 μm. Roughness of this magnitude may be sufficient to interfere with movement of fluid droplets.

Base 108 further comprises a cover 124. Cover 124 has a top side defining a working surface 146 and an underside facing towards addressing structure 128.

Cover 124 may be formed of one or more layers. In the depicted embodiment, cover 124 has a substrate layer formed of a dielectric material. Suitable dielectric materials may include polyimide film, polyethylene terephthalate (PET) film, and parylene film. A coating layer may be applied atop the substrate layer to define the working surface 146. For example, the coating layer may be spin-coated onto the substrate, or may be applied using another suitable technique. In some embodiments, the coating is hydrophobic. As will be apparent, a hydrophobic working surface 146 may improve droplet movement with water-based fluid droplets. In some embodiments, an oil phase, such as silicon oil, may be applied to the working surface 146, e.g., at the time of use. Such an oil phase may improve droplet movement on working surface 146 and may delay or prevent evaporation of droplets on the surface, particularly in applications with small droplet size (e.g., well below 1 μL) and relatively low ambient humidity.

In the depicted embodiment, cover 124 is flexible and is formed of an aluminum-coated polyimide film, with a thickness of 7.5 μm. The aluminum coating of cover 124 may be vapour-deposited and have a thickness of 30 nm. The hydrophobic coating may be formed by spin-coating the substrate with 0.5 wt % FluoroPolymer PFC 1104V, produced by Cytonix LLC in PFC 110 Fluoro Solvent, produced by Cytonix LLC, and drying the coated substrate at room temperature. In other embodiments, other dielectric materials may be used, and cover 124 may be partially or fully rigid.

A plurality of electrodes 150 are disposed on the underside of cover 124 opposite working surface 146. In the depicted embodiment, electrodes 150 are patterned directly onto the dielectric or substrate layer of cover 124. Conveniently, patterning electrodes 150 directly onto the underside of cover 124 minimizes any roughness of working surface 146 associated with the electrodes. However, other fabrication techniques are possible. For example, one or both of the substrate and coating may be applied to electrodes 150 by vapor-deposition.

Electrodes 150 are disposed in an array and are electrically coupled to and driven by electrode pads 134, which may in turn be coupled to electrical control system 164 by traces 120 and control contacts 116. For example, electrode pad 134a may be coupled to electrode 150a, while electrode pad 134b may be coupled to electrode 150b. In this way, each of electrodes 150 may be coupled to one of electrode pads 134.

In the depicted embodiment, the number and spatial arrangement of electrodes 150 corresponds to that of electrode pads 134, such that each electrode 150 corresponds to a single electrode pad 134 and vice-versa. Each electrode 150 may mate to a corresponding electrode pad 134 when cover 124 is placed atop addressing structure 128. However, in some embodiments, the number and spatial arrangement of electrodes 150 and electrode pads 134 may differ.

Voltage may be selectively applied to individual ones of electrodes 150 by way of electrical control system 164. Specifically, a voltage applied to a particular control contact 116 is applied to one or more corresponding electrodes 150 through the associated trace 120 and electrode pad 134.

A voltage signal may be applied to an electrode 150 while the adjacent electrodes 150 are grounded or held at another reference voltage. Such application of voltage to an electrode 150 may create a potential difference between that electrode and an adjacent electrode. The potential difference in turn creates electrostatic forces, which may act on a fluid droplet on working surface 146 and cause movement of the droplet.

Specifically, as depicted in FIG. 1C, application of a voltage to electrode 150b by way of electrode pad 134b creates electrostatic forces urging droplet 158 across working surface 146 and towards electrode 150b. In order for the electrostatic forces to move droplet 158 from electrode 150a to 150b, the electrodes must be positioned sufficiently closely to one another for electrostatic forces generated by the voltage at electrode 150b to affect droplet 158. The range at which such interaction can occur may be influenced by, for example, the type of fluid in the droplet, the size (volume) of the droplet, the viscosity of the droplet and friction between droplet and working surface 146, and the signal frequency and magnitude of voltage applied to electrode 150b.

As shown in FIG. 1C, no routing components are present on the underside of cover 124. Accordingly, electrodes 150 on cover 124 need not be spaced to accommodate conductive traces.

Electrode pads 134 and electrodes 150 are formed independently of one another and may have different sizes, i.e., different dimensions or surface area. Electrode pads 134 and electrodes 150 may also have different pitch. That is, the gap 154 between adjacent electrodes 150 may differ from the gap 142 between adjacent electrode pads 134. In particular, addressing structure 128 may provide a relatively large electrode pad gap 142 to accommodate conductive traces 120 while electrodes 150 may simultaneously have a small electrode gap 154 and be densely configured in an array on cover 124.

For example, as shown in FIG. 1C, adjacent electrodes 150a and 150b have greater area than the corresponding electrode pads 134a, 134b and the gap 154 between electrodes 150a, 150b is smaller than the gap 142 between electrode pads 134a, 134b. The sizes of electrodes 150 and gap 154 may be independent of the sizes of electrode pads 134 and gap 142, provided that the electrodes align with the corresponding electrode pads 134, such that the electrodes may be electrically coupled to the electrode pads 134 when cover 124 is installed atop addressing structure 128.

Larger electrodes 150 and smaller gaps 154 between electrodes may improve the manipulation of droplets 158 disposed on working surface 146. That is, electrostatic forces generated by application of voltage to electrodes may more easily cause movement of droplets 158 at adjacent electrodes if the spacing between those electrodes is small, because a droplet 158 may more easily overlap with adjacent electrodes 150.

Cover 124 may also provide a smooth working surface 146 without deep vertical trenches or ruts between adjacent electrodes 150. Specifically, cover 124 may be formed of a dielectric substrate and coating selected to be conducive to consistent droplet movement. In particular, cover 124 may have low surface roughness and a hydrophobic coating. Cover 124 may also isolate working surface 146 from roughness on the surface of addressing structure 128. That is, cover 124 may be supported atop electrode pads 134, such that roughness associated with the prominence of electrode pads 134 above the remainder of addressing structure 128 is reduced or eliminated.

In embodiments with a flexible cover 124, sagging of the cover may be possible in regions between electrode pads 134. Such sagging would result in height variations, i.e., contours or surface roughness on working surface 146. Fill material 135 may therefore be applied to addressing structure 128 between electrode pads 134. Fill material may include, for example, solder mask material, non-conductive moldable material, polydimethyl siloxane (PDMS), photoresists such as SU-8, small particles such as glass pearls, or small particles in an adhesive (e.g., glue or epoxy) matrix. Such fill material may reduce the apparent roughness of addressing structure 128 and may support cover 124 between the routing electrode pads 134, further reducing contours or roughness of working surface 146.

The two-part structure of addressing structure 128 and cover 124 may allow for the device to have tightly-spaced electrodes 150, while limiting the surface roughness that would typically be associated with microfluidics devices having addressing structures including a PCB. Moreover, the two-part structure may allow for easier and more cost-effective fabrication than conventional techniques. For example, addressing structure 128 may be fabricated using inexpensive PCB manufacturing techniques with larger or coarser components, which would typically result in high surface roughness. However, such roughness may be mitigated by cover 124, such that an acceptable working surface 146 may be achieved with relatively inexpensive fabrication techniques.

Referring to FIG. 1B, electrodes 150 may also include electrodes of more than one shape and size. Driving electrodes 151 may be smaller and more numerous than reservoir electrodes 153 and dispensing electrodes 155. Reservoir electrodes 153 and dispensing electrodes 155 may be disposed on the periphery of cover 124, and driving electrodes 151 configured in an array proximate the center of cover 124. Reservoir electrodes 153 may be used for collection of fluid and dispensing electrodes 155 which may be used to dispense droplets 158 from reservoir electrodes 153 onto driving electrodes 151 for use in a process, e.g., for an experiment. As depicted, driving electrodes may have an electrode gap of 100 μm. 120 electrodes are present in microfluidics device 100, including 104 driving electrodes, 8 dispensing electrodes and 8 reservoir electrodes. In the depicted embodiment, driving electrodes 151 are approximately 2.5 mm×2.5 mm. Dispensing electrodes 155 are approximately 2.5 mm×5.0 mm, and reservoir electrodes 153 are approximately 10 mm×7.5 mm. In other embodiments, electrodes 150 may include fewer or more electrodes, which may be configured in an array or some other pattern, and may be smaller or larger than described above.

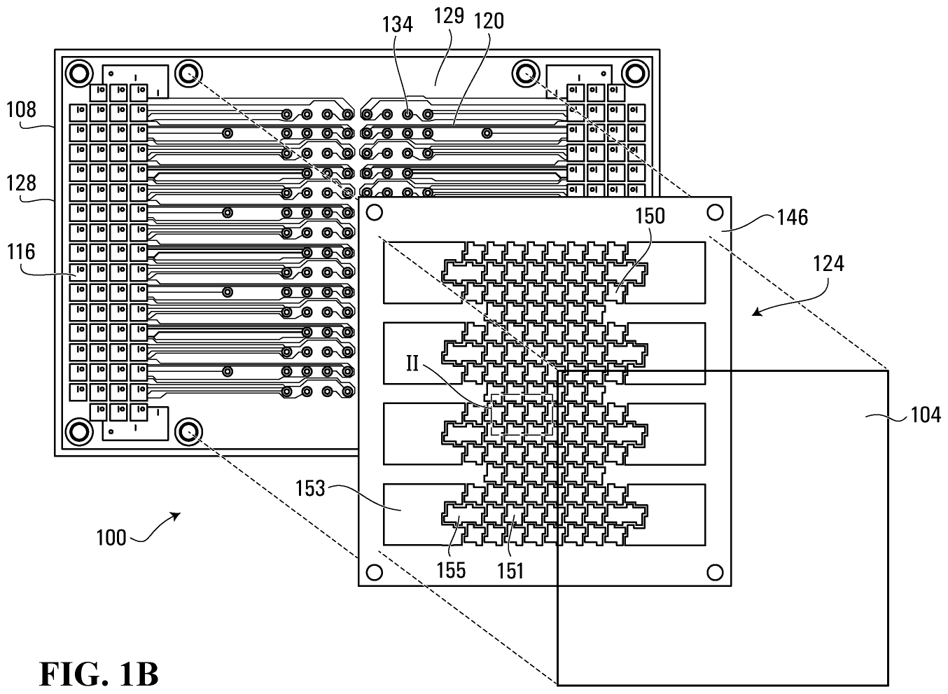

Electrodes 150 may be patterned in a variety of shapes, which need not correspond to the shapes of electrode pads 134. FIG. 2 depicts an enlarged view of the region labelled Il in FIG. 1B, showing example driving electrodes 151 beneath cover 124 in greater detail. In the depicted embodiment, driving electrodes 151 are interdigitated. That is, driving electrodes 151 have complementary or interlocking projections. Such projections may promote interaction of electrostatic forces created at one electrode with droplets 158 at adjacent electrodes. Specifically, droplets 158 may more readily overlap two of driving electrodes 151 that are adjacent, such that electrostatic fields at either electrode are more likely to interact with the droplets. For example, a droplet 158, disposed at the edge of driving electrode 151a may also overlap electrode 151b because the electrodes are interdigitated. This may contribute to reliable operation of the microfluidics device 100. For example, droplet 158, disposed at the edge of driving electrode 151a may also overlap driving electrode 151b because driving electrodes 151 are interdigitated. One or both of reservoir electrodes 153 and dispensing electrodes 155 may be interdigitated in the same manner.

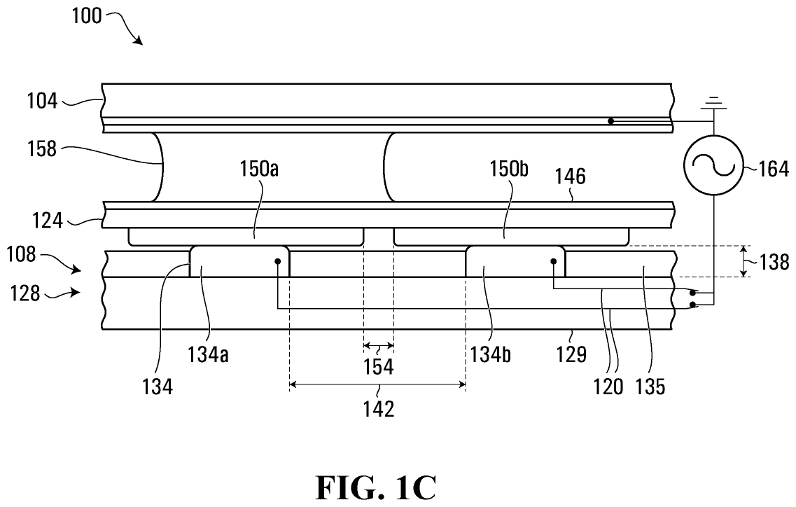

Cover 124 may be permanently or removably installed atop addressing structure 128. FIG. 3 illustrates an example installation technique. As shown in FIG. 3, cover 124 is held against addressing structure 128 using vacuum pressure from an external vacuum device.

The vacuum device includes a vacuum pump 424 connected with a vacuum chamber 412, which includes an array of through-holes 420. The vacuum chamber may be formed by 3-D printing or other suitable techniques.

Addressing structure 128 may be formed with corresponding through-holes 428. Addressing structure 128 is disposed on vacuum chamber 412 in such a way that the array of through-holes 420 line up with addressing structure through-holes 428, and the through-holes 428 communicate with the vacuum chamber 412. In an example, addressing structure 128 may be aligned on vacuum device surface 416 using alignment devices such as pins disposed on vacuum device surface 416. For example, alignment pins may include four vertical alignment pins disposed on vacuum chamber, which may each be 2 mm in diameter and correspond substantially to four alignment through-holes disposed on the corners or edges of addressing structure 128. A seal may be formed at the interface of vacuum chamber 412 and addressing structure 128. For example, a gasket may be interposed between the vacuum chamber and addressing structure around the periphery of the vacuum chamber.

Some or all of electrode pads 134 may be formed with hollow vias and may be disposed on addressing structure 128 in such a way that the vias align with addressing structure through-holes 428, which together may form through-holes from the bottom of addressing structure 128, through to the top surfaces of electrode pads 134.

When vacuum pump 424 is activated, vacuum is generated in vacuum chamber 412, creating a suction force 432 through addressing structure through holes 428 and into vacuum chamber 412. A seal may be defined between cover 124 and addressing structure 128. Vacuum pressure may be continuously applied to vacuum chamber 412. Alternatively, a vacuum may be created, then the vacuum chamber may be sealed to maintain vacuum pressure. Suction force 432 may act on cover 124 and bias electrodes 150 towards electrode pads 134, such that electrodes 150 are electrically coupled with electrode pads 134. For example, suction force 432 may act on cover 124 disposed on addressing structure 128, since suction force 432 may attract cover 124 towards electrode pad 134c and electrode pad 134d. Specifically, electrode 150a and electrode 150b may be biased towards electrode pad 134c and electrode pad 134d, respectively, such that electrode 150a and electrode 150b are electrically coupled with electrode pad 134c and electrode pad 134d.

Vacuum pressure may pull cover 124 taut against addressing structure 128, such that wrinkles on cover 124 are reduced or eliminated. Thus, mounting of cover in this manner may provide a smooth working surface 146.

In an example, the array of through-holes 420 may include 64 through-holes that are 1 mm in diameter each. However, the number and size of through-holes 420, 428 may vary. For example, the number and size of through-holes 420, 428 may depend on the physical size of microfluidics device 100 and the number of electrodes 150 and electrode pads 134. Larger numbers of through-holes may permit more even application of pressure to cover 124. Accordingly, for a large microfluidics device 100 with a large number of electrodes 150, a large number of through-holes may be preferred. In an example, 336 through-holes that are 1 mm in diameter each may be provided.

Additionally or alternatively, a series of channels (e.g., trenches) may be provided on the surface of addressing structure 128, in communication with one another and with a vacuum source, e.g., with vacuum chamber 412 by way of through-holes. The channels may distribute vacuum pressure across the underside of cover 124.

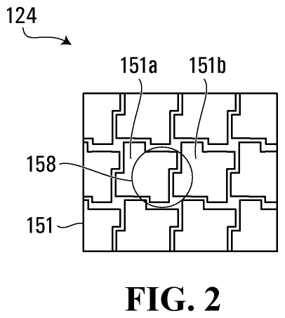

Conveniently, when attached by vacuum pressure, cover 124 may be easily removable from base addressing structure 128. Specifically, vacuum pump 424 may be deactivated, eliminating vacuum 404 and suction force 432. Cover 124 may thus be removed from addressing structure 128 without damaging cover 124, addressing structure 128 or microfluidics device 100 generally. FIG. 4 depicts lifting of an example cover 124 away from addressing structure 128. Details of the underside of cover 124 are omitted for clarity.

Removable attachment of cover 124 and addressing structure 128 permits addressing structure 128 to be used with multiple different covers. For example, covers 124 may be disposable and replaceable, such that addressing structure 128 can easily be re-used by replacing the cover 124. The cover may be fabricated relatively inexpensively, so that such re-use of addressing structure 128 is cost-effective.

Multiple covers 124 may also be compatible with a common addressing structure 128 and interchangeable according to requirements of a droplet manipulation process to be performed. For example, a cover with a regular grid of rectangular electrodes may be interchanged with a cover having interdigitated electrodes based for example on the nature and quantity of reagents to be used and the operations to be performed using those reagents.

In some embodiments, through-holes 428 may be used for purposes other than, or in addition to, vacuum attachment. For example, through-holes 428 may be used for illumination. Specifically, a light source may be placed below base 108, such that light passes through through-holes 428 to illuminate samples on working surface 146. Additionally or alternatively, through-holes 428 may be used to apply a treatment. For example, samples may be heated by placing a heat source below base 108 and forcing hot air through through-holes 428 or samples may be exposed to laser light transmitted through through-holes 428, or a magnetic field may be applied through through-holes 428, e.g., to collect particles. In such embodiments, additional through-holes may be provided in cover 124. Such additional through-holes may be aligned with some or all of through-holes 428 to allow passage of light or a treatment such as heat through the working surface 146.

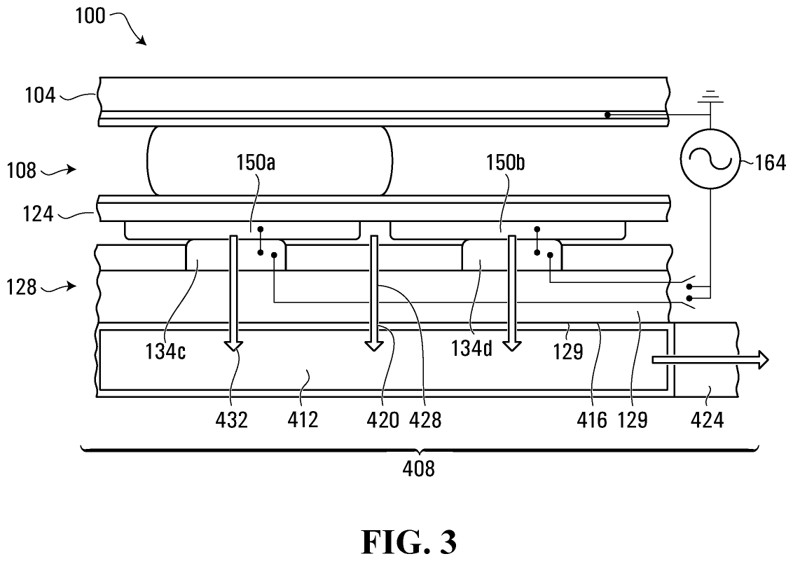

As described above, driving electrodes 151 are interdigitated. The number and size of interdigitations may vary. For example, FIG. 5 illustrates a working surface 146 with a large number of small interdigitations on each driving electrode 151′. As shown in FIG. 5, each interdigitation projects only a small distance from the driving electrode 151′. Consequently, driving electrodes 151′ are substantially rectangular, with toothed, interlocking sides.

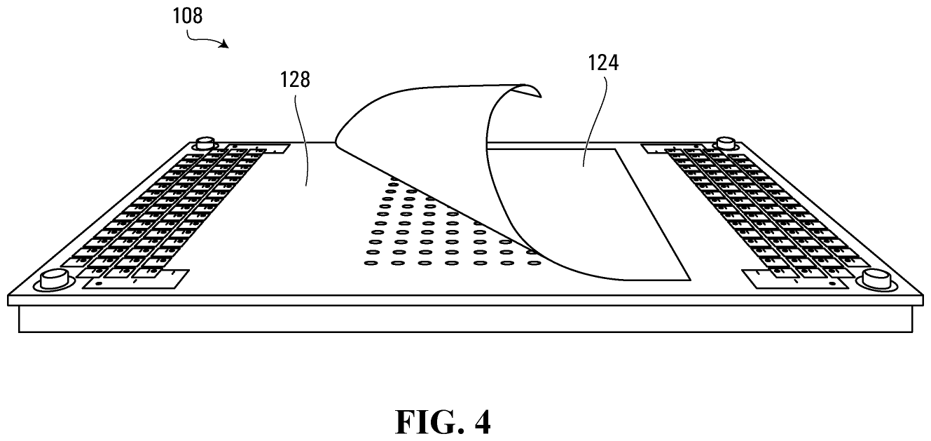

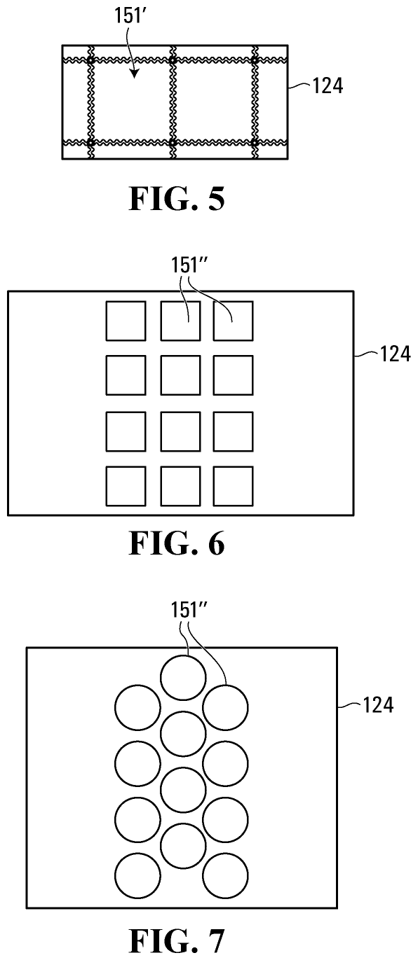

Driving electrodes may also have non-interdigitated shapes. For example, FIGS. 6-7 schematically depict working surfaces with rectangular driving electrodes 151″ and circular driving electrodes 151′″, respectively.

All of the depicted driving electrodes 151, 151′, 151″, 151′″ are arranged in regular geometric patterns. For example, electrodes 151, 151′, 151″ are generally arranged in grid patterns, and electrodes 151′″ are arranged in alternating offset rows. However, in other embodiments, electrodes may be arranged differently. For example, electrodes may be arranged in concentric rings, other geometric shapes, or in no pattern.

In each of the above-depicted embodiments, the driving electrodes 151, 151′, 151″, 151′″ are of consistent size and shape. In other embodiments, driving electrodes of multiple sizes and shapes may be present.

Reservoir electrodes 153 and dispensing electrodes 155 may also be formed in any of the shapes described herein with reference to driving electrodes, or any combination thereof.

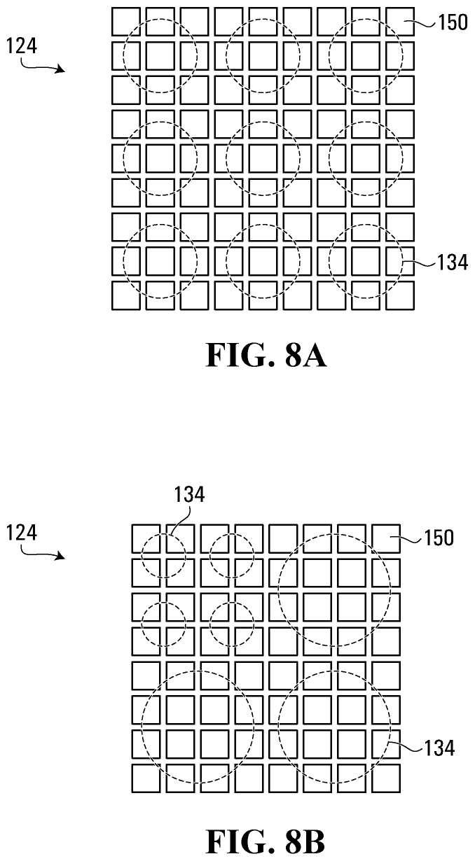

In some embodiments, the number, size or layout of electrodes 150 and electrode pads 134 may differ. For example, FIG. 8A-8B depicts a cover 124 with a grid of electrodes 150, used with multiple different layouts of electrode pads. The positions of electrode pads 134 are shown in broken lines. As shown in FIG. 8A, electrode pads 134 are larger than electrodes 150 and spaced at a larger pitch. Each electrode pad 134 is centered under a group of nine electrodes and contacts each of the nine electrodes in that group, such that when an electrode pad 134 is activated, all nine corresponding electrodes 150 are activated.

A microfluidics device may include electrode pads 134 of multiple different sizes and spacings. For example, as shown in FIG. 8B, a cover 124 with a grid of electrodes 150 is positioned over three large electrode pads 134, each centered under a group of nine corresponding electrodes 150 and contacting each of those electrodes, and four small electrode pads 134, each centered under a group of four corresponding electrodes and contacting each of those electrodes. Activation of a large electrode pad 134 activates all nine corresponding electrodes 150, and activation of a small electrode pad 134 activates all four corresponding electrodes 150.

Each group of electrodes 150 corresponding to a single electrode pad 134 may be used as a single “virtual” electrode. That is a group of nine electrodes 150 centered over and in contact with a single electrode pad 134 may function as if it was a single electrode of the same size as the entire 3×3 electrode group.

In some embodiments, standardized covers 124 with grids of small electrodes may be provided, and the layout and size of electrode pads 134 may be used to define a layout of virtual electrodes, i.e., a layout of electrode groups that function together as a single electrode.

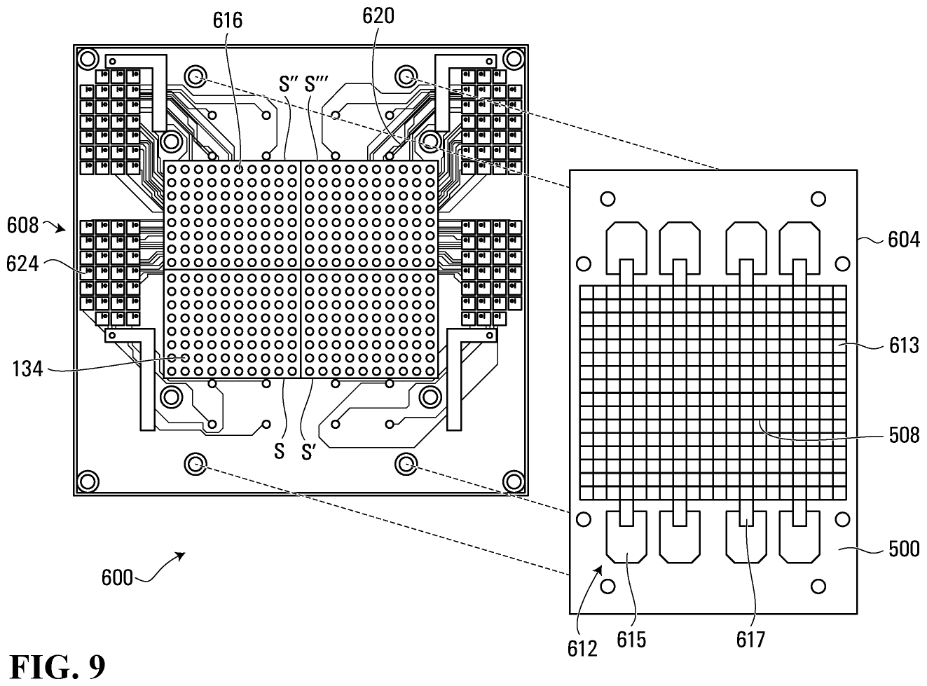

In some embodiments, some electrodes and electrode pads may be connected in parallel with one another. FIG. 9 illustrates an example of such a base 600. Base 600 includes a cover 604 and an addressing structure 608. Like components to those of base 108 are indicated with like reference characters and will not be described again in detail.

Addressing structure 608 may be formed of a PCB and may be rigid. Addressing structure 608 may include one or more layers. For example, addressing structure 608 may be a PCB with six layers.

Cover 604 may include working surface 500 and electrodes 612 disposed on cover 604 opposite working surface 500. Electrodes 612 may include driving electrodes 613, reservoir electrodes 615 and dispensing electrodes 617. As shown, driving electrodes 613, reservoir electrodes 615 and dispensing electrodes 617 are rectangular. However, the electrodes may be any shape. Driving electrodes 613 have an electrode gap 508 of 30 μm. In total, electrodes 612 may include an array of 336 electrodes. Base 600 may include 320 driving electrodes 613, 8 dispensing electrodes 617 and 8 reservoir electrodes 615. Driving electrodes 613 may be approximately 2.5 mm×2.5 mm. Dispensing electrodes 617 may be approximately 2.5 mm×5.0 mm, and reservoir electrodes 615 may be approximately 6 mm×4.5 mm. In other embodiments, electrodes 612 may include fewer or more electrodes, which may be configured in an array or some other pattern.

Electrodes 612 are coupled to electrode pads 134 and to control contacts 116 by way of conductive traces (not shown). The conductive traces may be routed in a bus layer of addressing structure 608, such that the bus layer is disposed in one of the lower layers of addressing structure 608. For example, addressing structure 608 may include 336 electrode pads 616 that must each be connected to one of conductive traces. To simplify routing, the bus layer of addressing structure 608 may include multiple layers of addressing structure 608, which may be a PCB. Some of electrode pads 134 may share conductive traces, such that driving one of conductive traces 620 with an electrical bias or control signal may also drive more than one of electrode pads 134. In other words, some of electrode pads 616 may be connected in parallel to one of conductive traces.

Specifically, as depicted, the array of electrodes 612 is divided into four quadrants S, S′, S″, S″. Each quadrant contains an identical array of electrodes 612. Each electrode in a quadrant is connected in parallel with the corresponding electrodes, i.e., the electrodes in corresponding positions, in each of the other quadrants.

Alternatively, each electrode 612 and electrode pad 134 may have a unique trace, but some of conductive traces may be coupled to common bottom plate contact pads 624, such that driving one of bottom plate contact pads 624 with a DC bias or electrical control signal may also drive multiple conductive traces connected to that contact pad, and the electrode pads and electrodes coupled thereto. In other words, some of conductive traces may be connected in parallel to one of bottom plate contact pads 624.

Conveniently, base 600 may allow for simultaneous performance of multiple instances of a droplet manipulation process, e.g., multiple instances of an experiment. For example, by providing control signals to electrodes in each of quadrants S, S′, S″, S′″ in parallel, droplets may be simultaneously moved in each quadrant in a like manner.

For example, a base 600 with 336 electrodes 612 may include an array of driving electrodes 613 laid out in a 16×20 array of rows and column, which may be further divided into four analogous 8×10 sub-arrays, wherein corresponding driving electrodes 613 in each sub-array may be coupled in parallel to the same one of bottom plate control contacts 116. The remaining 16 of electrodes 612 may be reservoir electrodes 615 and dispensing electrodes 617, and each of reservoir electrodes 615 and dispensing electrodes 617 may be connected to a unique one of bottom plate control contacts 116, such that electrical control system 164 may address the eight reservoir electrodes 615 and eight dispensing electrodes 617 independently.

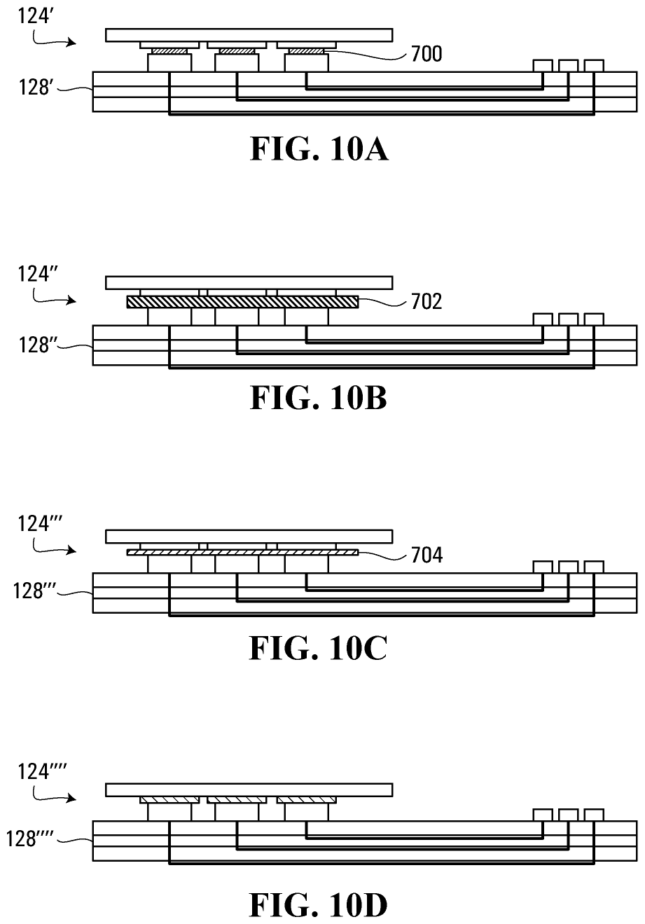

Cover 124 and addressing structure 128 may be removably or permanently attached to one another using techniques other than vacuum pressure. FIGS. 10A-10D illustrate other example cover attachment techniques.

FIG. 10A depicts a cover 124′ attached to an addressing structure 128′ using an isotropic conductive adhesive 700, i.e., an adhesive material that is electrically conductive in all directions. Each electrode of cover 124′ is mechanically attached to and electrically coupled to the corresponding electrode pad of addressing structure 128′ by a separate piece of adhesive material. The pieces of adhesive material are separated from one another, such that they are not in electrical contact. Suitable adhesives may include LOCTITE™ electrically-conductive adhesives made by Henkel Adhesive Technologies. Attachment of cover 124′ and addressing structure 128′ in this manner may permit independent production of the cover and addressing structure, and provide a permanently-attached, ready to use device.

FIG. 10B depicts a cover 124″ attached to an addressing structure 128″ using an anisotropic adhesive material 702, i.e., a material that is electrically conductive in only a single direction. A single piece of anisotropic adhesive may be used to mechanically couple multiple or all electrodes of cover 124″ to the corresponding electrode pads of addressing structure 128″. The anisotropic adhesive is oriented to be conductive in the vertical direction, but substantially non-conductive in horizontal directions. Accordingly, the anisotropic adhesive electrically couples each electrode to its corresponding electrode pad, but insulates adjacent electrodes from one another. An example of a suitable anisotropic adhesive material may include Anisotropic Conductive Film Adhesive 7303 made by 3M. Attachment of cover 124″ and addressing structure 128″ in this manner may be easier than attachment as depicted in FIG. 10A, in that less precision is required for application of the adhesive.

FIG. 10C depicts a cover 124′″ attached to an addressing structure 128′″ using an adhesive 704 with a high dielectric constant. Each electrode of cover 124′″ is capacitively coupled to the corresponding electrode pad of addressing structure 128″. A single piece of adhesive material may be used to couple multiple electrodes to their corresponding electrode pads; however, since the electrodes are not connected to each other, each electrode and its corresponding electrode pad may be independently driven by the electrical control system despite sharing a single piece of adhesive dielectric material. An example of a suitable adhesive with high dielectric constant may include cyanoethyl pullulan.

FIG. 10D depicts a cover 124″″ attached to an addressing structure 128″″ by static adhesion. For example, cover 124″″ may adhere to addressing structure 128″″ by electrostatic attraction.

In some embodiments, a cover may be removably attached to an addressing structure by magnetic attraction. In such embodiments, the cover may be produced using a material that can be magnetised, such as a ferromagnetic metal. For example, electrodes may be fabricated using a material capable of being magnetised, or particles of such a material may be added before or after (e.g. above or below) the electrodes, or embedded within the electrodes. Additionally or alternatively, dielectric material on the cover may be made from a thin film that can be magnetised. In some embodiments, a film that can be magnetised may be added to the cover, along with an additional insulating layer that does not conduct electricity in a horizontal (lateral) direction, to avoid shorting electrodes to one another. A magnetic field may then be applied to bias the electrodes against the electrode pads. The magnetic field may, for example, be applied using an electromagnet or permanent magnet placed below the base.

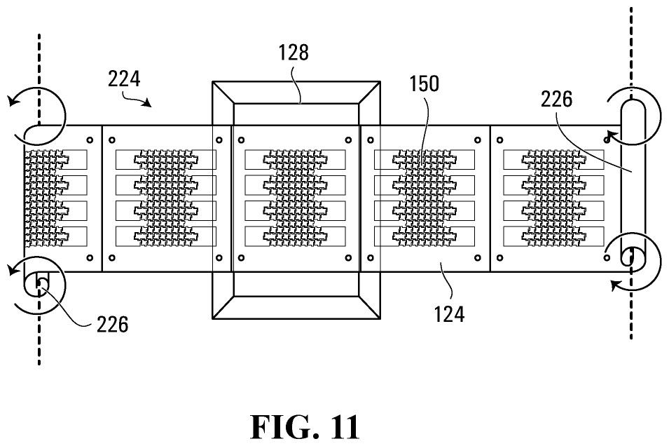

In further embodiments, cover 124 may be interchangeable with a new cover with respect to addressing structure 128. For example, as depicted in FIG. 11, cover 124 may be disposed on a single sheet 224, with working surface 146 disposed on the top of single sheet and electrodes 150 disposed on the underside of single sheet 224, i.e., opposite working surface 146. Multiple covers 124 may be attached end-to-end on a film or tape roll. A cover 124 may be readily removed and disposed of following use, and a replacement cover may be easily dispensed by advancing the roll, and mounted to the addressing structure 128, 608. The sheet 224 may be carried on a set of reels 226, such that a cover 124 may be replaced by advancing sheet 224 from one reel 226 to another reel 226. While positioned over addressing structure 128, the cover 124 may be held against the addressing structure, e.g., by vacuum pressure or static adhesion.

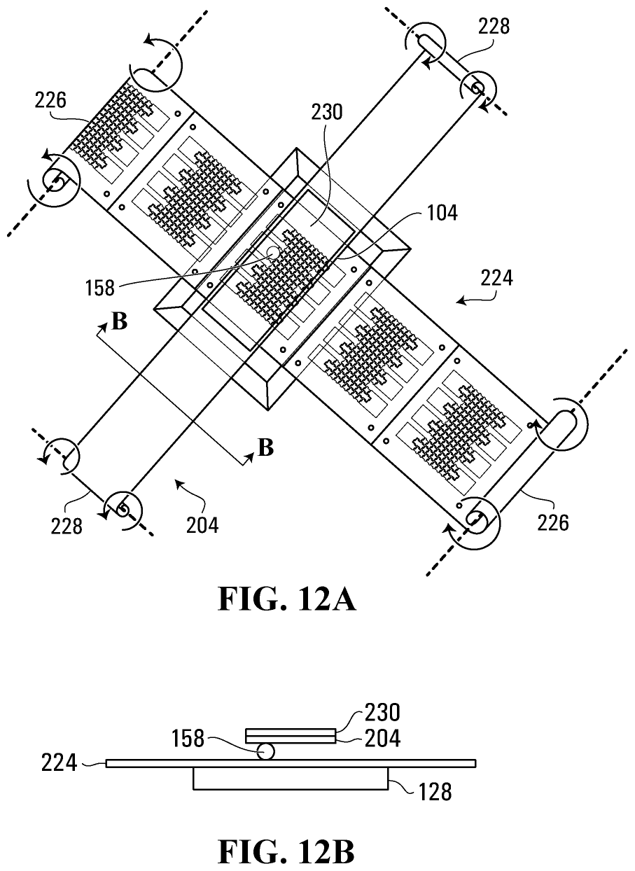

In some embodiments, both the top plate and cover may be disposed on respective flexible sheets. For example, as shown in FIGS. 12A-12B, multiple covers 124 are attached end-to-end as a single sheet 224, carried on reels 226. Likewise, top plate 104 is formed as a single sheet of material 204, carried on a set of reels 228. A cover 124 may be replaced by advancing sheet 224 on reels 226. A top plate 104 may be replaced by advancing sheet 204 on reels 228. The top plate may be positioned at a specific distance from cover 124 to provide headroom (i.e., a gap) for droplet 158 on the working surface. A guide may be provided to hold sheet 204 in position, with correct spacing above cover 124. For example, as depicted, a guide plate 230 is positioned above addressing structure 128 and sheet 224. Guide plate 230 may be supported at a desired height, e.g., using spacers. Sheet 204 may be pulled taut against guide plate 230 as the sheet is advanced over addressing structure 128 and cover sheet 224.

In some embodiments, top plate 104 may be curved, such that cover 124 may also be curved. In such embodiments, addressing structure 128 may also be curved, such that base 108 is also curved, or addressing structure 128 may alternatively include a curved component disposed on its surface to accommodate curved cover 124.

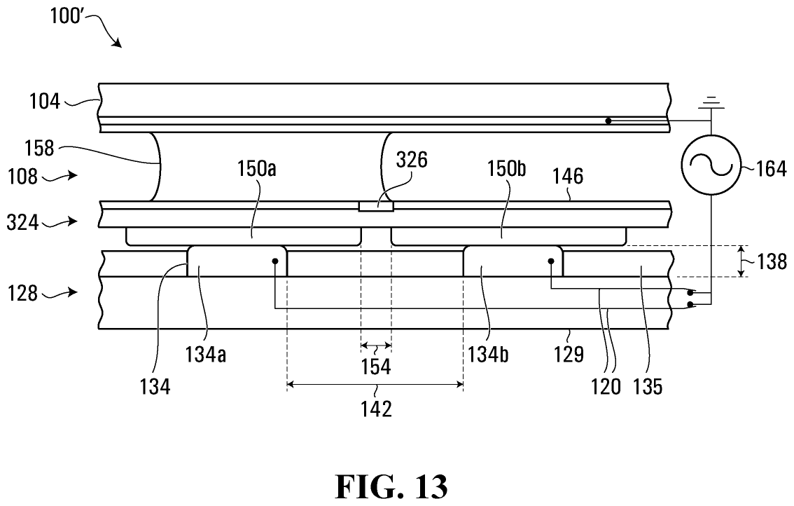

In some embodiments, multiple sets of electrodes may be patterned on a cover. For example, FIG. 13 depicts a cross-sectional view of a device 100′ with a cover 324 with electrodes 150 on one side of the cover (e.g., the underside) as described above, and ground electrodes 326 on the opposite (e.g., top) side of the cover. Thus, electrodes 150 and ground electrodes 326 are patterned onto the same physical structure, with a dielectric layer interposed between them.

Electrodes 150 and ground electrodes 326 interact with one another to produce electric fields for manipulating droplets 158. The strength of such fields may be increased when ground electrodes are present. That is, the electric fields resulting from interaction of electrodes 150 and ground electrodes 326 may be increased relative to an embodiment having only electrodes 150.

Patterning of ground electrodes 326 on cover 324 may allow for creation of strong electric fields, and therefore, effective droplet manipulation, with a relatively simple device configuration. For example, a top plate may be omitted, or a plain or hydrophobic-coated glass slide may be used as a top plate, and stronger electric fields may be produced than would otherwise be associated with such simple configurations. Alternatively, a top plate may be provided with electrical components used for purposes other than, or in addition to, manipulation of droplets. For example, auxiliary electrodes or sensors could be provided on the top plate for obtaining measurements.

In some embodiments, a microfluidics device may lack a top plate. In such embodiments, droplets may be placed on working surface 146. In other embodiments, a top plate may be provided with individual electrodes corresponding to electrodes 150. For example, some devices may comprise two opposed addressing structures and respective covers, with one cover and its associated addressing structure replacing the top plate such that droplets are positioned between the two covers and manipulated using electrodes of both covers.

As described above, addressing structures for the microfluidics devices include printed circuit boards. Printed circuit boards are a cost-effective technology for multi-layer routing. However, other types of addressing structures are possible. For example, contact pads, traces and electrode pads could be formed on a non-conductive film, such as PET film, by printing with electrically conductive ink, e.g., using an inkjet printer. A dielectric layer could then be defined by printing non-conductive ink atop the conductive ink, except over the electrode pads. Additional conductive material could then be printed atop the electrode pads so that the electrode pads are flush with the insulating layer. Addressing structures could also be patterned onto other rigid or non-rigid substrates, including semiconductor dies such as dies formed from silicon wafers.

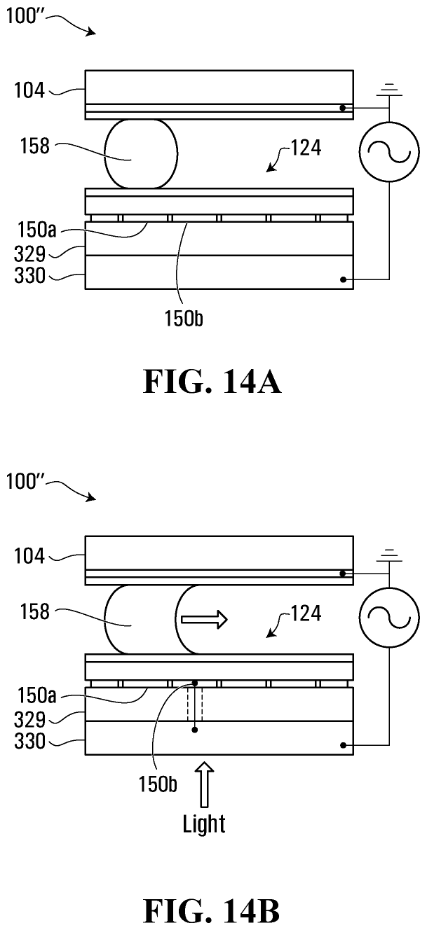

As described above, addressing structure 128 couples electrode pads to a control system by way of conductive (e.g., metallic) traces. Other structures for addressing electrodes are possible. For example, FIG. 14A depicts a device 100″ with an addressing structure 128′ comprising a photoconductive layer 329, namely, a layer of a material that is electrically conductive when exposed to light. Device 100′ includes a cover 124 and a top plate 104, which may be substantially identical to those included in the microfluidics device 100 described above.

Photoconductive layer 329 is positioned below cover 124, and interposed between the electrodes 150 of cover 124 and a conductive actuation layer 330 connected to a power supply (e.g., a control system).

Photoconductive layer 329 normally does not conduct electricity and therefore insulates electrodes 150 from actuation layer 330. Actuation layer 330 is at least partially transmissive of light, such that a light source/positioned below the actuation layer can illuminate photoconductive layer 329. For example, actuation layer 330 may be formed of a transparent or translucent electrically conductive material, or may comprise one or more conductive traces in a translucent or transparent substrate. Alternatively, the top plate (if present) and cover may be transparent or translucent such that light may be applied to the photoconductive layer from above.

The application of light to photoconductive layer 329 causes the illuminated portion of the photoconductive layer to become conductive. An actuation signal (i.e., a voltage) may be routed to one or more individual ones of electrodes 150 by selectively illuminating portions of photoconductive layer 329 while the actuation signal is applied to actuation layer 330. Thus, individual electrodes 150 may be addressed by controlled application of light. For example, as depicted in FIG. 14B, light is applied to a portion of photoconductive layer 329, creating a conductive path between electrode 150b and actuation layer 330, thereby applying a voltage to electrode 150b and creating a voltage differential between electrode 150b and an adjacent electrode 150a on which droplet 158 is positioned. The voltage differential exerts force on droplet 158, pulling the droplet toward electrode 150b.

Microfluidics devices according to the present disclosure may be used to manipulate both small and large fluid droplets. For example, during experimentation, testing or production procedures, droplets corresponding in size to, or smaller than, electrodes 150 may be manipulated. Alternatively, larger droplets forming pools of fluid that cover multiple electrodes may be placed on a working surface and moved, divided or mixed by manipulation using electrodes 150. The term “droplet” is intended to encompass fluid in any quantity suitable for manipulation as described herein.

Terms such as “above”, “below”, “top”, “bottom”, “underside” and the like are used herein are used herein to describe relative positions of components in reference to the orientation of components depicted in the figures, and not necessarily to the direction of gravity. Components may be used in different orientations. For example, a microfluidics device may be inverted so that the top plate is positioned beneath the cover (with reference to the direction of gravity).

Of course, the above-described embodiments are intended to be illustrative only and in no way limiting. The described embodiments are susceptible to many modifications of form, arrangement of parts, details and order of operation. The invention is intended to encompass all such modification within its scope, as defined by the claims.

What is claimed is:

1. A microfluidics device comprising:
a cover with a first side defining a working surface;
a plurality of electrodes on a second side of said cover for manipulation of fluid droplets on said working surface; and
an addressing structure for contacting said second side of said cover and coupled to a voltage source to selectively apply voltage to individual ones of said plurality of electrodes;
said cover mounted to said addressing structure to electrically couple said electrodes to said addressing structure.

2. The microfluidics device of claim 1, wherein said addressing structure comprises a plurality of electrode pads coupled to said voltage source by a plurality of conductive traces through said addressing structure.

3. The microfluidics device of claim 2, wherein said addressing structure comprises a printed circuit board.

4. The microfluidics device of claim 1 or claim 2, wherein said addressing structure comprises a semiconductor die.

5. The microfluidics device of claim 1, wherein said addressing structure comprises a photoconductive layer for selectively connecting ones of said electrodes to a voltage source by application of light.

6. The microfluidics device of any one of claims 1 to 5, wherein said cover comprises a sheet of dielectric material.

7. The microfluidics device of claim 6, wherein said plurality of electrodes are patterned onto said sheet of dielectric material.

8. The microfluidics device of claim 6 or claim 7, wherein said cover comprises aluminum-coated polyimide film.

9. The microfluidics device of any one of claims 1 to 8, wherein said cover comprises a flexible film.

10. The microfluidics device of any one of claims 1 to 9, wherein the thickness of said cover is between than 2.5 μm and 50 μm.

11. The microfluidics device of any one of claims 1 to 10, wherein the thickness of said cover is between 7.5 μm and 12.5 μm.

12. The microfluidics device of any one of claims 1 to 11, wherein said cover is removably mounted to said addressing structure.

13. The microfluidics device of claim 12, wherein said cover is removably mounted to said addressing structure by application of vacuum pressure.

14. The microfluidics device of claim 12, wherein said cover is mounted to said addressing structure using an adhesive.

15. The microfluidics device of any one of claims 1 to 14, wherein said addressing structure includes a plurality of through-holes.

16. The microfluidics device of claim 15, comprising a light source positioned to illuminate said working surface through said through-holes.

17. The microfluidics device of any one of claims 1 to 16, wherein said cover is dispensed from a roll.

18. The microfluidics device of any one of claims 1 to 17, comprising a plate positioned opposite said working surface for contacting a droplet on said working surface.

19. The microfluidics device of claim 3, wherein said voltage source is an integrated circuit for controlling said microfluidics device, said integrated circuit mounted to said printed circuit board and electrically coupled to said plurality of electrode pads.

20. The microfluidics device of claim 4, wherein said voltage source is an integrated circuit for controlling said microfluidics device, said integrated circuit formed on said semiconductor die.

21. The microfluidics device of claim 19 or claim 20, wherein said integrated circuit receives a data stream, said data stream comprising instructions for controlling said microfluidics device.

22. The microfluidics device of any one of claims 1 to 18, wherein said voltage source comprises a digital control system.

23. The microfluidics device of any one of claims 1 to 22, comprising a plurality of ground electrodes patterned on said first side of said cover.

24. A microfluidics method, comprising:
mounting a cover atop an addressing structure, said cover defining a working surface on a first side thereof and having a plurality of electrodes on a second side thereof, said addressing structure configured to selectively couple ones of said electrodes to a voltage source to cause movement of fluid droplets on said working surface.

25. The microfluidics method of claim 24, wherein said addressing structure comprises a plurality of electrode pads coupled to said voltage source by a plurality of conductive traces through said addressing structure.

26. The microfluidics method of claim 25, wherein said addressing structure comprises a printed circuit board.

27. The microfluidics method of claim 26, wherein said addressing structure comprises a semiconductor die.

28. The microfluidics method of claim 24, wherein said addressing structure comprises a photoconductive layer for selectively connecting ones of said electrodes to a voltage source by application of light.

29. The microfluidics method of any one of claims 24 to 28, wherein said cover comprises a flexible film.

30. The microfluidics method of any one of claims 24 to 29, comprising mounting said cover to said addressing structure by application of vacuum pressure.

31. The microfluidics method of any one of claims 24 to 29, comprising mounting said cover to said addressing structure using an adhesive.

32. The microfluidics method of claim 30 or claim 31, comprising removing said cover from said mounting structure and mounting a second cover atop said addressing structure.

33. The microfluidics method of claim 31, comprising dispensing said second cover by advancing a roll of film.

34. The microfluidics method of claim 26, wherein said voltage source is an integrated circuit for controlling said movement of fluid droplets on said working surface, said integrated circuit mounted to said printed circuit board and electrically coupled to said plurality of electrode pads.

35. The microfluidics method of claim 27, wherein said voltage source is an integrated circuit for controlling said movement of fluid droplets on said working surface, said integrated circuit formed on said semiconductor die.

36. The microfluidics method of claim 34 or claim 35, wherein said integrated circuit receives a data stream, said data stream comprising instructions for controlling said movement of fluid droplets on said working surface.

37. The microfluidics method of any one of claims 24 to 36, wherein said cover comprises a plurality of ground electrodes patterned on said first side.

38. A microfluidics device comprising:
a top plate;
a base, comprising:
a cover with a first side defining a working surface facing said top plate;
a plurality of electrodes on a second side of said cover for manipulation of fluid droplets on said working surface; and
an addressing structure comprising a plurality of electrode pads coupled to an electrical control system by a plurality of conductive traces through said addressing structure;
said cover mounted to said addressing structure to electrically couple said electrodes to said addressing structure.
